(19) United States
(12) Patent Application Publication
(10) Pub. No.: US 2009/0309754 A1
(43) Pub. Date: Dec. 17, 2009

(54) WIRELESS CURRENT TRANSFORMER

(76) Inventors: Jimmy Bou, Safety Harbor, FL (US); Michael Haas, New Port Richey, FL (US); James Michael Koepsell, Tampa, FL (US)

Correspondence Address: General Electric Company;GE Global Patent Operation, PO Box 861, 2 Corporate Drive, Suite 648, Shelton, CT, 06484, US

(21) Appl. No.: 12/139,885

(22) Filed: Jun. 16, 2008

(51) Int. Cl. G08C 17/00; G01R 22/00

(52) U.S. Cl. 340/870.02; 702/62

(57) ABSTRACT

The present disclosure describes a system for monitoring energy data having at least one wireless current transformer, a metering circuit configured to receive an analog signal from the current transformer and to calculate energy data, a wireless transmitter unit in circuit with the metering circuit which is configured to transmit the energy data, and a receiver unit having a receiver, a processor in circuit with the receiver and configured to collect the energy data; and a display connected to the processor and configured to display the energy data. A method and apparatus for monitoring energy data is also presented.

### BACKGROUND

The present invention relates to an apparatus, system and method for monitoring energy data. More specifically, the invention relates to monitoring electrical energy.

High voltage current transformers (hereinafter “CT” or “CT's”) are typically used by the electrical power industry to facilitate the safe measurement of large currents, often in the presence of extremely high voltage (e.g., voltage over 735 kV). CT's safely isolate measurement and control circuitry from the high voltage typically present in the current being measured. Hence, they are generally used by utility companies for metering purposes, protective relaying and overall monitoring of a power grid.

Commonly, CT's consist of large, oil-filled insulating columns that provide mechanical support for the large current transformer and ensure sufficient dielectric insulation from measurement point to ground. To gather the data and monitor the energy data, power plants typically hard-wire CT's to metering and/or relaying systems. Therefore, the CT's and the data gathering and processing site must be in reasonably close proximity.

Recently, wireless network communication systems have become increasingly beneficial to utility companies, used in meter-reading and relaying.

For example, Belski et al., U.S. Pat. No. 6,657,552 discloses a wireless system for communication and control of automated meter reading, which depends on a sensor to read utility usage. Elliot et al., U.S. patent application US 2002/0094799A1 discloses a wireless utility meter that is for use throughout a neighborhood and uses primarily Bluetooth communication. Mason Jr. et al., U.S. Pat. No. 7,187,906, discloses a self-configuring system to collect metering data using wireless communication as the primary means of collection.

While the above-described documents propose various wireless schemes for transmitting utility usage data, these wireless meters are used to monitor usage in residential settings, and are unable to withstand industrial applications in which voltage and current ratings are very high.

Accordingly, to date, there is no suitable system, apparatus or method for monitoring electrical energy data.

### BRIEF DESCRIPTION

The present disclosure describes a system, apparatus and method for monitoring energy data.

In a first embodiment, the invention provides a system for monitoring energy data comprising at least one wireless current transformer. The current transformer may comprise a metering circuit configured to receive an analog signal from the current transformer and to calculate energy data, a wireless transmitter unit in circuit with the metering circuit wherein the wireless transmitter unit is configured to transmit the energy data and a receiving unit. The receiving unit may comprise a receiver, a processor in circuit with the receiver and configured to collect the energy data, and a display connected to the processor and configured to display the energy data.

In a second embodiment, the invention provides a wireless current transformer, comprising a current transformer, a metering circuit configured to receive an analog signal from the current transformer and to calculate energy data and a wireless transmitter unit in circuit with the metering circuit, wherein the wireless transmitter unit is configured to transmit the energy data.

In a third embodiment, the invention provides a method for monitoring energy data comprising measuring energy data from a current transformer via an analog signal to a metering circuit, wirelessly transmitting the energy data via a wireless transmitter unit in circuit with metering circuit, receiving the energy data at a receiving station, collecting the energy data via a processor electronically connected to the receiver and displaying the energy data.

Other features and advantages of the disclosure will become apparent by reference to the following description taken in connection with the accompanying drawings.

### BRIEF DESCRIPTION OF THE DRAWINGS

Reference is now made briefly to the accompanying drawings, in which:

FIG. 1 is schematic diagram of an electrical energy monitoring system.

FIG. 2 a schematic diagram of electrical circuitry in accordance with embodiments of the present invention.

FIG. 3 is a diagrammatic representation of an exemplary wireless current transformer device to which embodiments of the present invention relate.

FIG. 4 is further diagrammatic representation of an exemplary wireless current transformer device to which embodiments of the present invention relate.

FIG. 5 is flow chart describing a step-wise method in accordance with a further embodiment of the present invention.

Like reference characters designate identical or corresponding components and units throughout the several views, which are not to scale unless otherwise indicated.

### DETAILED DESCRIPTION

One embodiment of the present invention involves a monitoring system which comprises a current transformer that sends an analog signal to a metering circuit, which in turn calculates energy data and sends the data via wireless communication to a processor. One particular advantage afforded by this invention is the ability to monitor relatively large current energy data from a remote location, e.g., up to approximately ten miles away from a plant site.

Specific configurations and arrangements of the claimed invention, discussed below with reference to the accompanying drawings, are for illustrative purposes only. Other configurations and arrangements that are within the purview of a skilled artisan can be made, used, or sold without departing from the spirit and scope of the appended claims. For example, while some embodiments of the invention are herein described with reference to a commercial plant site, a skilled artisan will recognize that embodiments of the invention can be implemented in any setting in which remote energy data monitoring is advantageous.

As used herein, an element or function recited in the singular and proceeded with the word “a” or “an” should be understood as not excluding plural said elements or functions, unless such exclusion is explicitly recited. Furthermore, references to “one embodiment” of the claimed invention should not be interpreted as excluding the existence of additional embodiments that also incorporate the recited features.

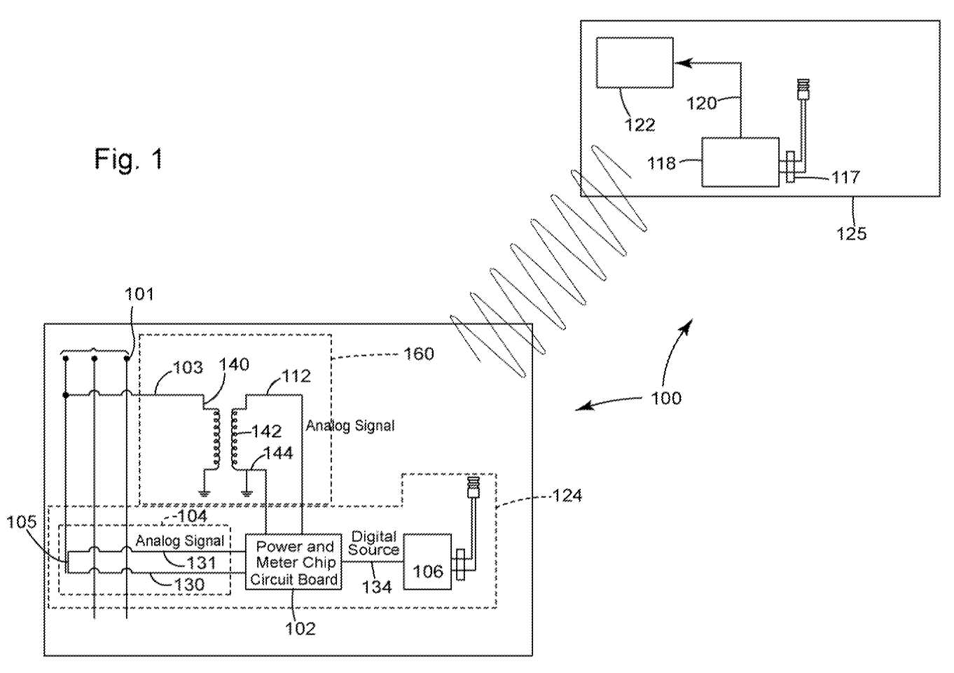

Referring now to FIG. 1, an exemplary system for monitoring energy data corresponding to one embodiment of the present invention is shown generally at 100. The monitoring system 100 is provided for monitoring a current level flowing through a power source line 101 and the monitoring system comprises a wireless current transformer 124 and a receiver unit 125. The wireless current transformer comprises a current transformer 104, a metering circuit 102, and a transmitter 106. The receiver unit 125 comprises a receiver 117 and a processor 118.

In this exemplary embodiment, the current transformer 104 comprises a coil 105 that may be looped around one phase of the power source line 101, which, as illustrated, is a three-phase electrical power transmission system.

The current transformer 104 may be connected to the metering circuit 102 via lines 130 and 131. The metering circuit 102 may be configured to calculate energy data including but not limited to voltage, current, power, kilowatt-hours, and power demand. For example, current level of the power source line 101 may be calculated, as is known by one of ordinary skill in the art, by measuring a current induced in the winding 105 of the current transformer 104 that is proportional to an alternating current flowing through each phase of the power source line 101. It will be understood that in the present embodiment, voltage level of the power source line 101 may be an estimated value. Estimated values include high voltages such as 735 kilovolts (kV) down to 480 Volts (V) for commercial manufacturing and power plant applications or 120V or 240V for residential purposes. Usage data such as kilowatt hours may be calculated to provide power consumption, e.g., for a particular machine and/or various machines working in a commercial manufacturing process.

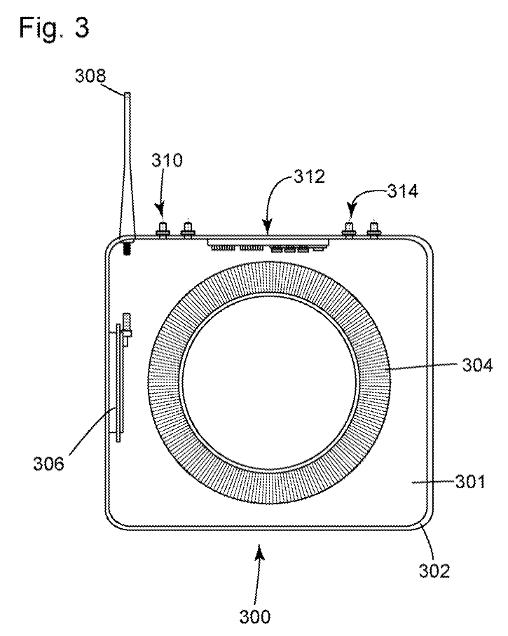

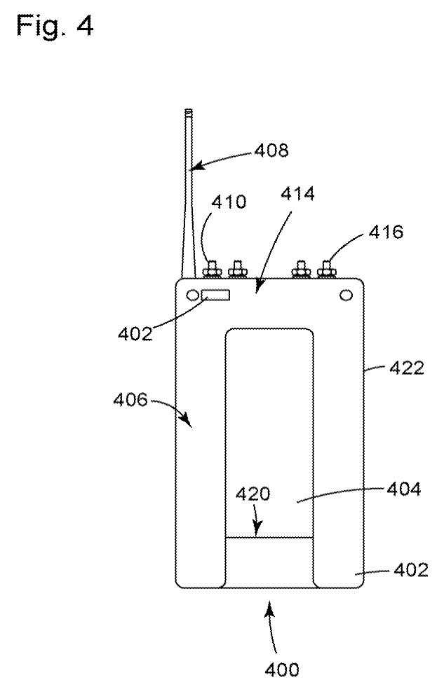

An optional embodiment is shown generally at 160 and may optionally be used in conjunction with the wireless CT unit shown generally at 124. For example, the wireless current transformer may include a potential transformer 140 electrically connected to power source line 101 via line 103. The potential transformer comprises a secondary winding 142 that may be connected to the metering circuit 102 via analog input signal line 112, and output signal line 144. Each line, 112 and 144, in turn, may be connected to the wireless current transformer 124 at voltage input terminals described and shown with reference to FIGS. 3 and 4 in more detail below. This embodiment may be optionally used where it is necessary or advantageous to supply a proportional voltage to the alternating voltage at each phase of the power source line 101, i.e., where accurately stepping down the voltage of a circuit to a value that can be safely and effectively used for operation of meters and relays is desired.

However, in an optional embodiment, the metering circuit 102 may be constructed to withstand high voltage (e.g., greater than 10 kV), such as those used in industrial applications and power plants. Furthermore, the current transformer 104 may comprise a solid-core CT, a split core CT, a toroidal core CT, a split bus bar CT, or busing model CTs. It is to be appreciated that the present invention may be adapted to fit the specifications of each different type of transformer. For instance, in industrial applications, a bus bar transformer may be looped around a high-voltage bus bar, and although not shown, may reside in switchboard or switchgear assemblies. In residential applications, for example, a split-core transformer may be wrapped around soft wiring. CT's suitable for use in the practice of these embodiments are manufactured and sold by Instrument Transformers, Inc, and can be found at the World Wide Web at http://www.geindustrial.com/products/static/iti/redirect.htm.

With further reference to FIG. 1, the metering circuit 102 may be connected via a digital source line 134 to the transmitter 106. The transmitter 106, which will be discussed further with reference to FIGS. 3 and 4, may be configured to transmit energy data, via wireless communication, to receiver 117. Wireless communication may comprise radio frequency (RF), Bluetooth®, satellite, wireless local area networks (WLAN), and the like. In accordance with a feature of the present invention, this allows all energy data to be collected, stored, accessed and maintained at a remote location. Furthermore, with reference to industrial applications, the transmitter obviates the need for manufacturers to run hardwire from each CT or CT stack to a central location for metering and relaying purposes.

Again with reference to FIG. 1, the receiver 117 is connected to a processor 118 that is, in turn, connected to a display 122 via line 120. The connection may be, for example, a Modbus serial PC connection. In the present embodiment, the processor 118 may be configured for real-time monitoring of energy data, storage, data calculations, and any coprocessor function applicable to any alternative embodiments of the present invention. Furthermore, the receiver may be self-configuring, i.e., it may be unnecessary to reconfigure the system or manually install any device drivers to access energy data from the transmitter.

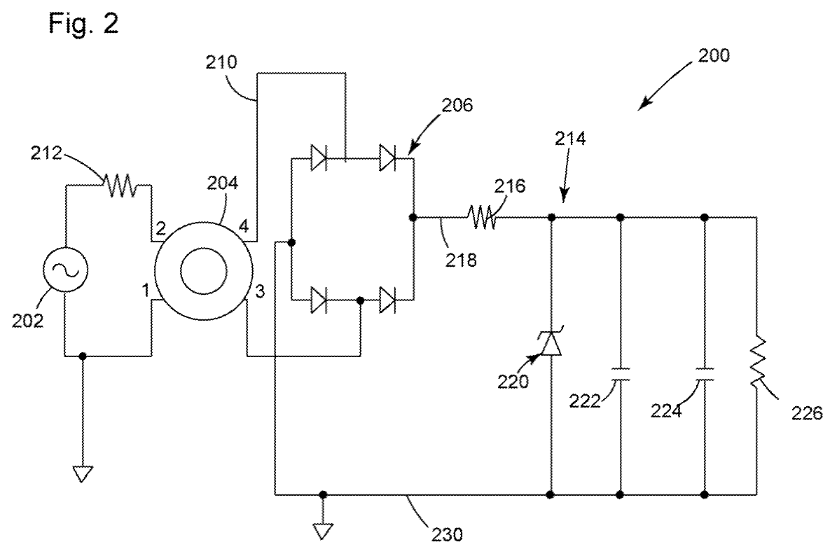

With reference now to FIG. 2, a self-powered portion of a metering circuit is shown generally at 200. The self powering circuit 200 comprises a power source line as shown in FIG. 1 (reference number 101), which is magnetically coupled with power winding CT 204 via input line 208, which is configured to step down the current and to up the voltage. The self-powered portion of the metering circuit further comprises a CT internal winding resistance 212.

A bridge rectifier 206 is further electrically connected to the CT output via line 210 on a positive side of the bridge and line 211 on a negative side of the bridge. The bridge rectifier comprises four diodes configured to provide full wave rectification and convert full AC input to DC output.

A smoothing network is also provided at 214. The smoothing network comprises resistor 216 in circuit with the bridge rectifier via line 218. The smoothing network further comprises a zener diode 220 in parallel with two capacitors 222, 224 and a resistor 226. An output line 230 is provided connecting the smoothing network 214 with the bridge rectifier 206. The current and voltage for powering the metering circuit is provided at I.

It is to be appreciated that the self-powered portion of the metering circuit may reside on the same board as the metering portion of the metering circuit. It is to be further appreciated that any analog device may be used as well.

Referring now to FIG. 3, an exemplary embodiment of a wireless CT apparatus is shown generally at 300. In this particular embodiment, the unit is configured to operate with a solid-core toroidal CT. Therefore, installation may most advantageously occur during installation of the wiring or bus bar itself. The wireless CT unit comprises a Radio Frequency (RF) transmitter 306, a solid core CT 304, an analog to digital (A/D) converter, power supply and metering circuit 312, and may optionally comprise current terminal output terminals 310 and voltage terminal input location 314.

In this exemplary embodiment, the shell casing 302 surrounds (encloses) the CT 304 and contains the unit's internal devices (not all shown), e.g., electrical and non-electrical devices, wires, processors, circuitry, metering circuit boards 312 and the like. Furthermore, the casing may act as a mounting conduit for devices advantageously located on the outside of the casing, e.g., wire terminals 310, 314, antenna 308, wireless transmitters 306 and the like.

Referring further to FIG. 3, RF transmitter 306 may be mounted to shell casing 302, and is connected electronically to the internal circuitry (not shown). RF transmitter 306 may be configured to transmit energy data gathered by an internal metering circuit. Transmission may be facilitated, in turn, by an electrical connection to antenna 308. For exemplary purposes only, this particular embodiment may be functional at, for example, 50-1000 amps, less than 600 volts, and may require a 5-15 KV shielded cable to sustain accurate measurement.

With reference now to FIG. 4, another embodiment of the wireless CT apparatus is shown generally at 400. In this embodiment, the CT is a split-core CT. Therefore, installation of the device may occur after the bus bar or soft wiring has been installed. The end-piece 420 is removable and thus allows the CT to be looped around existing wiring.

Similar to the embodiment illustrated in FIG. 3, the wireless CT unit in FIG. 4 comprises a wireless RF transmitter 406, a metering circuit 402, a split-core CT 404, an analog to digital (A/D) converter and power supply 414, and may optionally comprise current terminal output locations 410 and voltage terminal input location 416.

In this exemplary embodiment, the shell casing 422 surrounds (encloses) the CT 404 and contains the unit's internal devices (not all shown), e.g., electrical and non-electrical devices, wires, processors, circuitry, metering circuit boards 402 and the like. Furthermore, the casing may act as a mounting conduit for devices advantageously located on the outside of the casing, e.g., wire terminals 410, 416, antenna 408, wireless transmitters 406 and the like.

Referring further to FIG. 4, RF transmitter 406 may be mounted to shell casing 422, and is connected electronically to the internal circuitry (not shown). RF transmitter 406 may be configured to transmit energy data gathered by an internal metering circuit. Transmission may be facilitated, in turn, by an electrical connection to antenna 408. For exemplary purposes only, this particular embodiment may be functional at, for example, 50-1000 amps and less than 600 volts.

In another embodiment of the present invention, the invention provides a method for monitoring energy data comprising measuring energy data from a current transformer via an analog signal to a metering circuit, wirelessly transmitting the energy data via a wireless transmitter unit in circuit with metering circuit, receiving the energy data at a receiving station, collecting the energy data via a processor electronically connected to the receiver and displaying the energy data.

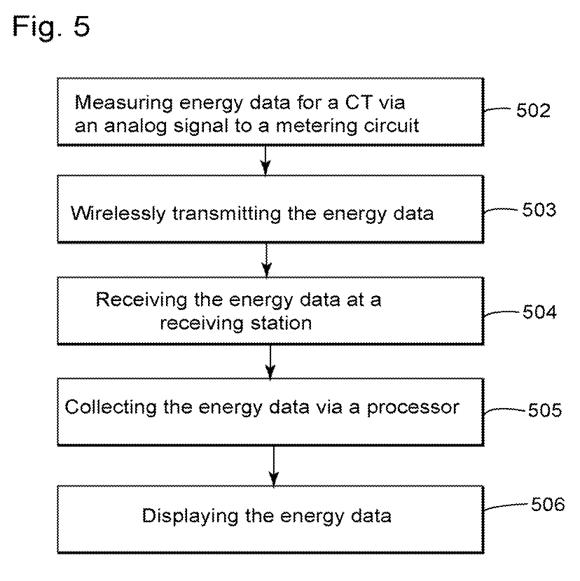

With reference to FIG. 5, there is shown a flow chart to better help illustrate method for monitoring energy data generally at 500. While the flowchart shows an exemplary step-by-step method, it is to be appreciated that a skilled artisan may rearrange or reorder the steps while maintaining like results.

Measuring energy data step 502 comprises utilization of a metering circuit to measure such data as current, voltage, kilowatt-hours, and power. In this exemplary embodiment, a current transformer may be looped around a three-phase source line and by providing a current in the secondary winding of the current transformer proportional to the alternating current flowing through its primary winding, current may be calculated by the metering circuit even in the presence of very high voltage.

Wirelessly transmitting the energy data step 503 comprises utilization of a wireless transmitter which may be electronically connected to the metering circuit. The transmitter may use, for instance, radio frequency, Bluetooth®, WLAN and the like to transmit data to a receiver. The receiving step 504 may comprise reception of energy data at a remote location. For example, it may be advantageous to store energy data at a site several miles away from a power plant for data regulation and confidentiality purposes

The processing step 505 may comprise gathering all energy data from the metering circuit. The processor may perform advanced calculations and statistical analyses, intelligent retrieval, data conversion and the like. The displaying step 506 comprises representing the data to an operator on, for example, on a computer monitor.

Although specific features of various embodiments of the invention may be shown in some drawings and not in others, this is for convenience only. In accordance with the principles of the invention, the feature(s) of one drawing may be combined with any or all of the features in any of the other drawings. The words “including”, “comprising”, “having”, and “with” as used herein are to be interpreted broadly and comprehensively and are not limited to any physical interconnection. Moreover, any embodiments disclosed herein are not to be interpreted as the only possible embodiments. Rather, modifications and other embodiments are intended to be included within the scope of the appended claims.

What is claimed is:

1. A system for monitoring energy data comprising:
at least one wireless current transformer comprising:
a current transformer;
a metering circuit configured to receive an analog signal from the current transformer and to calculate energy data;
a wireless transmitter unit in circuit with the metering circuit, wherein the wireless transmitter unit is configured to transmit the energy data; and
a receiver unit comprising:
a receiver;
a processor in circuit with the receiver and configured to collect the energy data; and
a display connected to the processor and configured to display the energy data.

2. The system of claim 1, wherein the processor is configured to calculate at least one of kilowatts, kilowatt-hours, current, voltage or power demand.

3. The system of claim 1, wherein the wireless transmitter unit is self-sustained.

4. The system of claim 1, wherein the current transformer comprises a split-core transformer or a solid core transformer.

5. The system of claim 1, wherein the receiver further comprises a Modbus serial computer connection

6. The system of claim 1, wherein the wireless unit further comprises at least one current terminal location, voltage terminal location, A/D converter, power supply and an antenna.

7. The system of claim 1, wherein the current transformer is a low or medium voltage current transformer.

8. The system of claim 1, wherein the metering circuit is configured to receive an at least one analog signal from the current transformer, and wherein the metering circuit utilizes the analog current to calculate at least one of current, voltage, power or energy.

9. A wireless current transformer, comprising:
a current transformer;
a metering circuit configured to receive an analog signal from the current transformer and to calculate energy data; and
a wireless transmitter unit in circuit with the metering circuit, wherein the wireless transmitter unit is configured to transmit the energy data.

10. The apparatus of claim 9, wherein the processor is configured to calculate at least one of kilowatts, kilowatt-hours, current, voltage or power demand.

11. The apparatus of claim 9, wherein the wireless transmitter unit is self-sustained.

12. The apparatus of claim 9, wherein the current transformer comprises a split-core transformer or a solid core transformer.

13. The apparatus of claim 9, wherein the wireless transmitter unit further comprises at least one current terminal location, A/D converter, power supply and antenna.

14. The apparatus of claim 9, wherein the current transformer is a low or medium voltage current transformer.

15. The apparatus of claim 9, wherein the metering circuit is configured to receive an at least one analog signal from the current transformer, and wherein the meter circuit utilizes the analog current to calculate at least one of current, voltage, power or energy.

16. A method for monitoring energy data comprising:
measuring energy data from a current transformer via an analog signal to a metering circuit;
wirelessly transmitting the energy data via a wireless transmitter unit in circuit with metering circuit;
receiving the energy data at a receiving station;
collecting the energy data via a processor electronically connected to the receiver;
displaying the energy data.

17. The method of claim 16, wherein the collecting step comprises calculating at least one of kilowatts, kilowatt-hours, current, voltage or power demand.

18. The method of claim 16, wherein the wireless transmitter unit is self-sustained.

19. The method of claim 16, wherein the measuring step is configured to operate with a split-core transformer or a solid core transformer.

20. The method of claim 16, wherein the wireless transmitter unit comprises a Modbus serial computer connection

21. The method of claim 16, wherein the wireless transmitter unit further comprises at least one current terminal location, A/D converter, power supply and antenna.

22. The method of claim 16, wherein the current transformer is a low or medium voltage current transformer.

23. The method of claim 16, wherein the metering circuit is configured to receive an at least one analog signal from the current transformer, and wherein the meter circuit utilizes the analog current to calculate at least one of current, voltage, power or energy.
